(19) United States
(12) Patent Application Publication
(10) Pub. No.: US 2025/0329005 A1
(43) Pub. Date: Oct. 23, 2025

(54) STATE DETECTION METHOD AND STATE DETECTION DEVICE

(71) Applicant: SCREEN Holdings Co., Ltd., Kyoto (JP)

(72) Inventor: Shinji SHIMIZU, Kyoto-shi, Kyoto (JP)

(21) Appl. No.: 18/867,412

(22) PCT Filed: Mar. 8, 2023
(86) PCT No.: PCT/JP2023/008737

§ 371 Date: Nov. 19, 2024

(30) Foreign Application Priority Data
May 26, 2022 (JP) 2022-085935

(51) Int. Cl. G06T 7/00

(52) U.S. Cl. CPC G06T 7/0004; G06T 2207/20024; G06T 2207/30148

(57) ABSTRACT

Suppressed is reduction of accuracy of detecting a state of a target even in a case there is a limitation on an imaging direction in which an image of an imaging target can be taken. A state detection method disclosed in the specification of the present application includes: a step of taking an image of at least one imaging target regarding processing of a substrate by an imaging part and outputting the image; a step of applying a filter previously prepared to the image in accordance with the imaging target; and a step of detecting a state of the imaging target based on the image to which the filter is applied, wherein a filter coefficient of the filter applied to the image is corrected based on a positional relationship between the imaging target whose image is taken and the imaging part.

### TECHNICAL FIELD

A technique disclosed in the specification of the present application relates to a state detection technique in substrate processing. A substrate as a processing target includes a semiconductor wafer, a glass substrate for a liquid crystal display device, a flat panel display (FPD) substrate such as an organic electroluminescence (EL) display device, an optical disk substrate, a magnetic disk substrate, a magnetic optical disk substrate, a photomask glass substrate, a ceramic substrate, a field emission display (that is to say, FED) substrate, or solar battery substrate, for example.

### BACKGROUND ART

Conventionally, in a process of manufacturing a semiconductor device, for example, a processing solution such as pure water, a photoresist solution, or an etching solution is supplied to a substrate to perform substrate processing such as washing processing and resist application processing, for example.

In such substrate processing, an amount of a processing solution discharged from a nozzle is monitored, for example.

### PRIOR ART DOCUMENTS

### Patent Document(s)

Patent Document 1: Japanese Patent Application Laid-Open No. 2021-190511

### SUMMARY

### Problem to be Solved by the Invention

In a chamber where the substrate processing is performed, since a plurality of configurations used for the substrate processing are disposed, arrangement of a camera for performing monitoring described above is also limited. As a result, the camera should obliquely view a monitoring target, and a shape of the monitoring target is deformed in image data obtained by the camera in some cases.

In such a case, accuracy of image processing such as filter processing is reduced, and accuracy of detecting a state of the monitoring target is also reduced.

A technique disclosed in the specification of the present application therefore has been made to solve the above problems, and is a technique for suppressing reduction of accuracy of detecting a state of a target even when there is a limitation on an imaging direction in which an image of an imaging target can be taken.

### Means to Solve the Problem

A state detection method according to a first aspect of a technique disclosed in the specification of the present application includes: a step of taking an image of at least one imaging target regarding processing of a substrate by an imaging part and outputting the image; a step of applying a filter previously prepared to the image in accordance with the imaging target; and a step of detecting a state of the imaging target based on the image to which the filter is applied, wherein a filter coefficient of the filter applied to the image is corrected based on a positional relationship between the imaging target whose image is taken and the imaging part.

A state detection method according to a second aspect of a technique disclosed in the specification of the present application relates to the state detection method according to the first aspect, wherein a direction as a reference in taking the image of the imaging target is a reference direction, an angle between an imaging direction as a direction in which the imaging part takes the image of the imaging target and the reference direction is an inclination angle, and the filter coefficient is corrected based on the inclination angle.

A state detection method according to a third aspect of a technique disclosed in the specification of the present application relates to the state detection method according to the second aspect, wherein the filter is a two-dimensional filter, and the filter coefficient located at an end portion of the filter in a direction in which the imaging direction is inclined with respect to the reference direction is corrected to 0.

A state detection method according to a fourth aspect of a technique disclosed in the specification of the present application relates to the state detection method according to any one of the first to third aspects, wherein the plurality of imaging targets include a first imaging target and a second imaging target located in a position different from the first imaging target, and the step of applying the filter to the image is a step of switching the filter between the image of the first imaging target and the image of the second imaging target and applying the filter.

A state detection device according to a fifth aspect of a technique disclosed in the specification of the present application includes: an imaging part for taking an image of at least one imaging target and outputting the image; and a detection part for detecting a state of the imaging target based on the image to which a filter previously prepared in accordance with the imaging target is applied, wherein a filter coefficient of the filter applied to the image is corrected based on a positional relationship between the imaging target whose image is taken and the imaging part.

### Effects of the Invention

According to at least the first and fifth aspects of the technique disclosed in the specification of the present application, the filter coefficient is corrected based on the positional relationship between the imaging target and the imaging part; thus, appropriate filter processing is achieved, and reduction of accuracy of detecting the state of the target can be suppressed.

These and other objects, features, aspects and advantages of the technique disclosed in the specification of the present application will become more apparent from the following detailed description when taken in conjunction with the accompanying diagrams.

### BRIEF DESCRIPTION OF DRAWINGS

FIG. 1 A plan view illustrating an example of a layout of an inner part of a substrate processing device relating to the present embodiment.

FIG. 2 A plan view schematically illustrating an example of a configuration of a processing unit.

FIG. 3 A cross-sectional view schematically illustrating an example of the configuration of the processing unit.

FIG. 4 A plan view schematically illustrating an example of a movement route of a nozzle.

FIG. 5 A function block diagram schematically illustrating an example of an inner configuration of a controller.

FIG. 6 A flow chart illustrating an example of a flow of substrate processing.

FIG. 7 A diagram schematically illustrating an example of image data obtained from a camera when monitor processing is performed.

FIG. 8 A diagram schematically illustrating an example of image data obtained from the camera when monitor processing is performed.

FIG. 9 A diagram schematically illustrating an example of differential image data.

FIG. 10 A diagram illustrating a dry region illustrated in FIG. 8 in a plan view.

FIG. 11 A diagram illustrating the dry region illustrated in FIG. 8 in a perspective view.

FIG. 12 A diagram illustrating an example of a filter coefficient of a filter applied to each pixel in a ROI.

FIG. 13 A diagram illustrating another example of the filter coefficient of the filter applied to each pixel in the ROI.

FIG. 14 A diagram illustrating an example of recipe information.

### DESCRIPTION OF EMBODIMENT(S)

Embodiments are described hereinafter with reference to the appended diagrams. Although detailed features, for example, are also described in the following embodiments for explaining a technique, they are exemplifications, and all of them are not necessary features to be able to implement the embodiments.

Since the diagrams are schematically illustrated, a configuration is appropriately omitted or simplified in the diagrams for convenience of the description. A mutual relationship of sizes and positions of configurations each illustrated in the different diagrams is not necessarily illustrated accurately, but may be appropriately changed. A hatching may be assigned to easily understand contents of the embodiments also in the diagrams which are not cross-sectional views but are plan views, for example.

In the description hereinafter, the same reference numerals will be assigned to the similar constituent elements in the diagrams, and the constituent elements having the same reference numeral have the same name and function. Accordingly, the detailed description on them may be omitted to avoid a repetition in some cases.

An expression “comprising”, “including”, or “having” a certain constituent element is not an exclusive expression for excluding the presence of the other constituent elements unless otherwise described in the specification of the present application.

In the description in the specification of the present application, even when ordinal numbers such as “first” or “second” are stated, the terms are used to facilitate understanding of contents of embodiments for convenience, and therefore, the usage of the ordinal numbers does not limit the indication of the ordinal numbers to ordering in the contents of the embodiments.

In the description in the specification of the present application, even when the terms indicating a specific position or direction such as “up”, “down”, “left”, “right”, “side”, “bottom”, “front”, “back”, for example, are used, these terms are used to facilitate understanding of contents of embodiments for convenience, and therefore, they have no relationship to a position or a direction in an actual implement.

### <Embodiment>

Described hereinafter are state detection method and a state detection device relating to the present embodiment.

### <Whole Configuration of Substrate Processing Device>

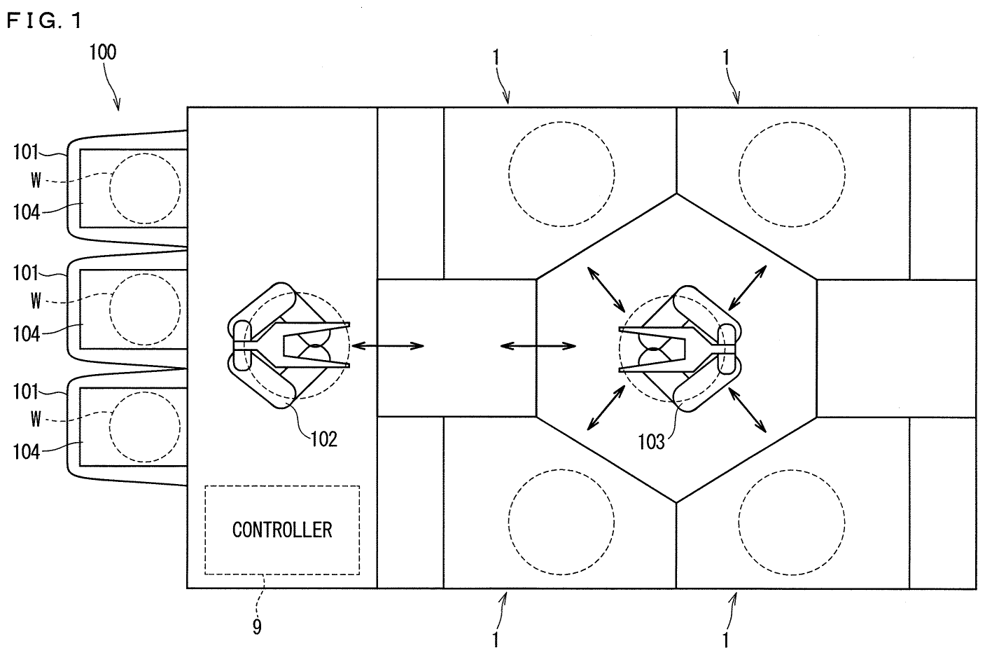

FIG. 1 is a plan view illustrating an example of a layout of an inner part of a substrate processing device 100 relating to the present embodiment. As exemplified in FIG. 1, the substrate processing device 100 is a sheet-like processing device performing processing on a substrate W as a processing target one by one.

The substrate processing device 100 relating to the present embodiment performs washing processing on the substrate W as a silicon substrate having a circular thin plate-like shape using a rinse solution such as a chemical solution and pure water, and then performs drying processing.

Applied as the chemical solution described above is, for example, a mixed solution of ammonia and hydrogen peroxide solution (SC1), a mixed water solution of hydrochloric acid and hydrogen peroxide solution (SC2), or a DHF solution (dilute hydrofluoric acid).

A chemical solution, a rinse solution, and an organic solvent, for example, are collectively referred to as “a processing solution” in the description hereinafter. “The processing solution” also includes a chemical solution not only for the washing processing but also for removing an unnecessary film or a chemical solution for etching.

The substrate processing device 100 includes a plurality of processing units 1, a load port 101, an indexer robot 102, a main transfer robot 103, and a controller 9.

Adoptable as a carrier 104 is a front opening unified pod (FOUP) housing the substrate W in an enclosed space, a standard mechanical inter face (SMIF) pod, or an open cassette (OC) exposing the substrate W to outside air. The indexer robot 102 transfers the substrate W between the carrier 104 and the main transfer robot 103.

The processing unit 1 performs solution processing and drying processing on one substrate W. Twelve processing units 1 having similar configurations are disposed in the substrate processing device 100 relating to the present embodiment.

Specifically, four towers each including three processing units 1 stacked in a vertical direction are disposed to surround the main transfer robot 103.

FIG. 1 schematically illustrates one of the processing units 1 stacked in three stages. The number of the processing units 1 in the substrate processing device 100 is not limited to 12, but may appropriately be changed.

The main transfer robot 103 is disposed in a center of four towers made up of the stacked processing units 1. The main transfer robot 103 transports the substrate W as a processing target received from the indexer robot 102 into each processing unit. The main transfer robot 103 transports the substrate W which has been processed from each processing unit 1 and passes the substrate W to the indexer robot 102. The controller 9 controls an operation of each constituent element of the substrate processing device 100.

One of twelve processing units 1 provided to the substrate processing device 100 is described hereinafter. The other processing unit 1 has the same configuration except that an arrangement relationship of the nozzle is different.

### <Processing Unit>

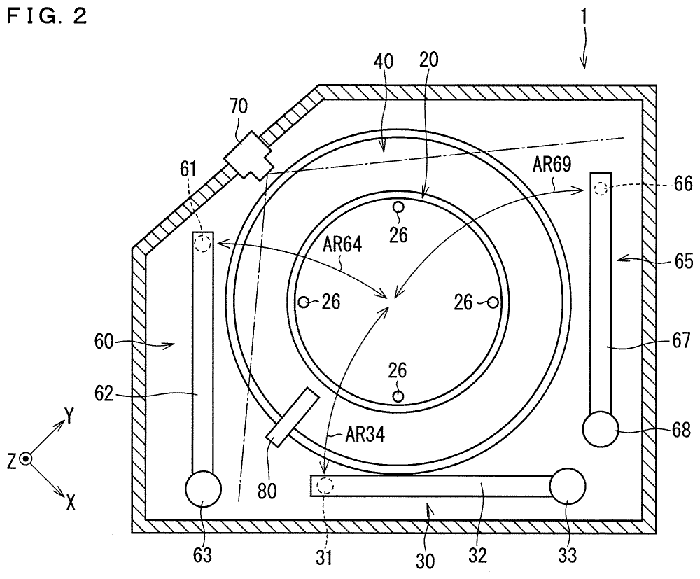

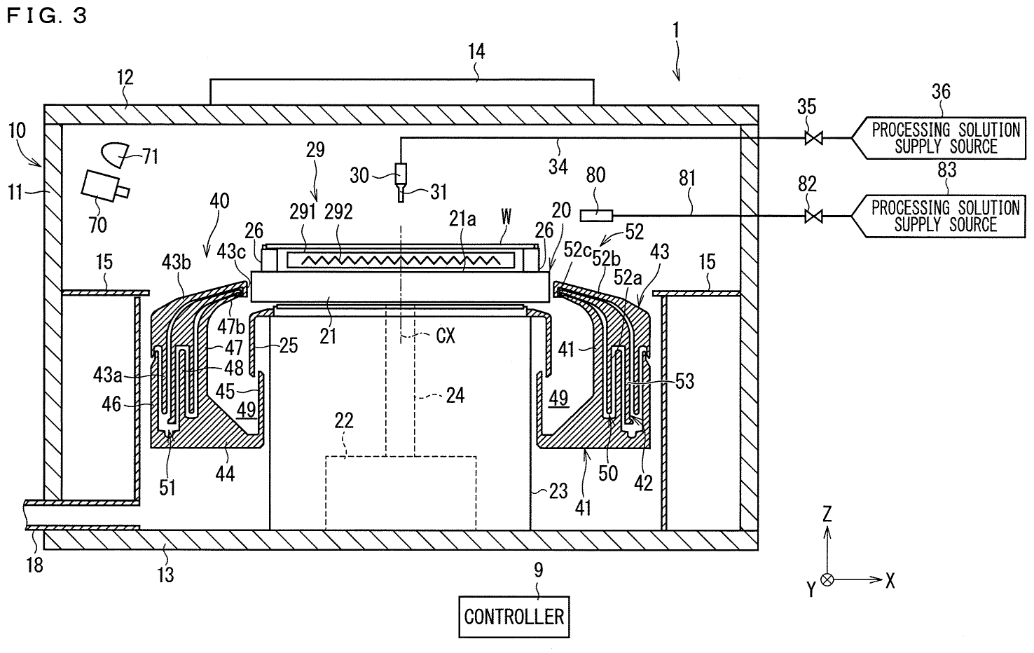

One of twelve processing units 1 provided to the substrate processing device 100 is described next. FIG. 2 is a plan view schematically illustrating an example of a configuration of the processing unit 1. FIG. 3 is a cross-sectional view schematically illustrating an example of a configuration of the processing unit 1.

As exemplified in FIG. 2 and FIG. 3, the processing unit 1 includes, in a chamber 10, a spin chuck 20, as an example of a substrate holding part, a heating part 29, a nozzle 30, a nozzle 60, a nozzle 65, a fixing nozzle 80, a processing cup 40, and a camera 70.

The chamber 10 includes a sidewall 11 disposed along a vertical direction, a ceiling wall 12 closing an upper side of a space surrounded by the sidewall 11, and a floor wall 13 closing a lower side. A space surrounded by the sidewall 11, the ceiling wall 12, and the floor wall 13 serves as a processing space. Provided to a part of the sidewall 11 of the chamber 10 are a transfer port (not shown in the diagrams) for the main transfer robot 103 to transport the substrate W and a shutter (not shown in the diagrams) for opening and closing the transfer port.

Attached to the ceiling wall 12 of the chamber 10 is a fan filer unit (FFU) 14 further cleaning air in a clean room in which the substrate processing device 100 is disposed and supplying the air to the processing space in the chamber 10. The fan filter unit 14 includes a fan and a filter for taking in the air in the clean room and sending the air into the chamber 10 (high efficiency particulate air (HEPA) filter, for example), and forms a down flow of clean air in the processing space in the chamber 10. A punching plate in which a large number of vent holes are formed may be provided immediately below the ceiling wall 12 for uniformly dispersing the clean air supplied from the fan filter unit 14.

The spin chuck 20 holds the substrate W in a horizontal posture (that is to say, a posture in which a normal line follows a vertical direction). The spin chuck 20 includes a disk-like spin base 21 fixed in a horizontal posture on an upper end of a rotational axis 24 extending in the vertical direction. A spin motor 22 rotating the rotational axis 24 is provided to a lower side of the spin base 21. The spin motor 22 rotates the spin base 21 in a horizontal plane via the rotational axis 24. A cylindrical cover member 23 is provided to surround the spin motor 22 and the rotational axis 24.

An outer diameter of the disk-like spin base 21 is slightly larger than a diameter of the circular substrate W held by the spin chuck 20. Thus, the spin base 21 has an upper surface 21a facing a whole lower surface of the substrate W to be held by the spin base 21.

A plurality of (four in the present embodiment) chuck pins 26 are provided to a peripheral edge part of an upper surface 21a of the spin base 21. The plurality of chuck pins 26 are disposed at regular intervals (at intervals of 90 degrees in a case of four chuck pins 26 as with the present embodiment) along a circumference corresponding to the peripheral edge of the circular substrate W. Each chuck pin 26 is provided to be able to be driven between a holding position having contact with the peripheral edge of the substrate W and a release position away from the peripheral edge of the substrate W. The plurality of chuck pins 26 are driven in conjunction with each other by a link mechanism not shown in the diagram but housed in the spin base 21. The spin chuck 20 stops the plurality of chuck pins 26 at each holding position, thereby being able to hold the substrate W in the horizontal posture while bringing the substrate W close to the upper surface 21a on an upper side of the spin base 21 (refer to FIG. 3), and stops the plurality of chuck pins 26 at each release position, thereby being able to release holding of the substrate W.

A lower end of the cover member 23 covering the spin motor 22 is fixed to the floor wall 13 of the chamber 10, and an upper end thereof reaches an immediately lower side of the spin base 21. Provided to an upper end part of the cover member 23 is a flanged member 25 protruding from the cover member 23 to an outer side in substantially a horizontal direction and further extending to be bended downward. When the spin motor 22 rotates the rotational axis 24 while the spin chuck 20 holds the substrate W by grasping the substrate W by the plurality of chuck pins 26, the substrate W can be rotated along a rotational axis line CX along the vertical direction passing through a center of the substrate W. The controller 9 controls the driving of the spin motor 22.

The nozzle 30 has a configuration that a discharge head 31 is attached to a tip end of a nozzle arm 32. A base end side of the nozzle arm 32 is connected and fixed to a nozzle base table 33. The nozzle base table 33 can be pivoted around an axis along the vertical direction by a motor not shown in the diagrams. When the nozzle base table 33 is pivoted, the nozzle 30 is moved in an arc-like form in a space on an upper side of the spin chuck 20 as illustrated by an arrow AR34 in FIG. 2.

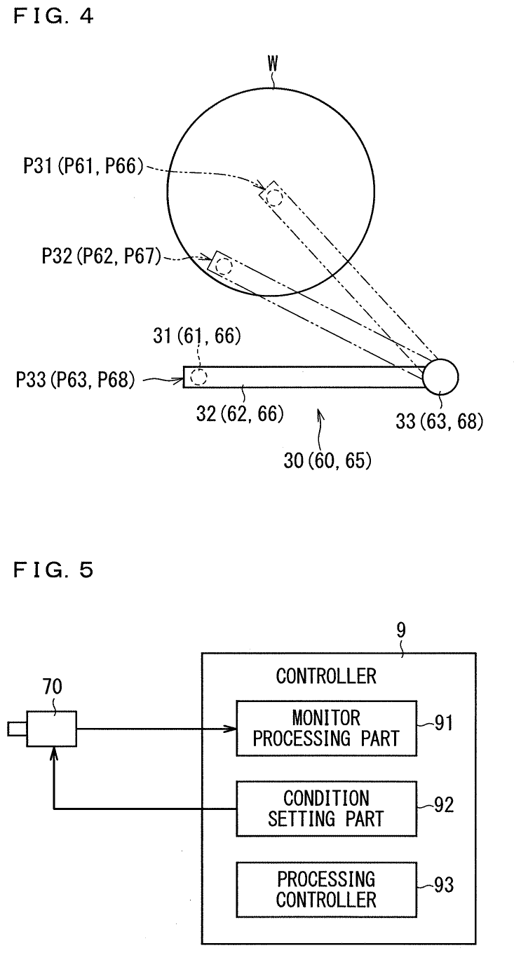

FIG. 4 is a plan view schematically illustrating an example of a movement route of the nozzle 30. As exemplified in FIG. 4, the discharge head 31 of the nozzle 30 is moved along a circumferential direction around the nozzle base table 33 by the rotation of the nozzle base table 33. The nozzle 30 can be stopped at an optional position. In the example in FIG. 4, the nozzle 30 can be stopped at each of a center position P31, a peripheral edge position P32, and a standby position P33.

The center position P31 is a position where the discharge head 31 faces a center part of the substrate W held by the spin chuck 20 in the vertical direction. When the nozzle 30 located at the center position P31 discharges a processing solution to the upper surface of the substrate W in rotation, the processing solution can be supplied to the whole upper surface of the substrate W. Accordingly, processing can be performed on the whole upper surface of the substrate W.

The peripheral edge position P32 is a position where the discharge head 31 faces the peripheral edge part of the substrate W held by the spin chuck 20 in the vertical direction. The nozzle 30 may discharge the processing solution to the upper surface of the substrate W in rotation while being located at the peripheral edge position P32. Accordingly, the processing solution can be discharged to only the peripheral edge part of the upper surface of the substrate W, and processing can be performed on only the peripheral edge part of the substrate W (so-called bevel processing).

The nozzle 30 can also discharge the processing solution to the upper surface of the substrate W in rotation while being swinging between the center position P31 and the peripheral edge position P32. Also in this case, the processing can be performed on the whole upper surface of the substrate W.

In the meanwhile, the nozzle 30 may not discharge the processing solution in the peripheral edge position P32. For example, the peripheral edge position P32 may be a relay position where the nozzle 30 temporarily stands ready when being moved from the center position P31 to the standby position P33.

The standby position P33 is a position where the discharge head 31 does not face the substrate W held by the spin chuck 20 in the vertical direction. A standby pod housing the discharge head 31 of the nozzle 30 may be provided in the standby position P33.

As exemplified in FIG. 3, the nozzle 30 is connected to a processing solution supply source 36 via a supply pipe 34. A valve 35 is provided to the supply pipe 34. The valve 35 opens and closes a flow path of the supply pipe 34. When the valve 35 is opened, the processing solution supply source 36 can supply the processing solution to the nozzle 30 through the supply pipe 34. The nozzle 30 may have a configuration that plural types of processing solutions (including at least pure water) are supplied.

A nozzle 60 and a nozzle 65 are further provided to the processing unit 1 relating to the present embodiment in addition to the nozzle 30 described above. The nozzle 60 and the nozzle 65 have the same configuration as the nozzle 30 described above. That is to say, the nozzle 60 has a configuration that a discharge head 61 is attached to a tip end of a nozzle arm 62. The nozzle 60 is moved in the arc-like form in the space on the upper side of the spin chuck 20 as illustrated by an arrow AR64 by a nozzle base table 63 connected to a base end side of the nozzle arm 62. A relative positional relationship between a center position P61, a peripheral edge position P62, and a standby position P63 located on a movement route of the nozzle 60 is similar to that between the center position P31, the peripheral edge position P32, and the standby position P33.

In the similar manner, the nozzle 65 has a configuration that a discharge head 66 is attached to a tip end of a nozzle arm 67. The nozzle 65 is moved in the arc-like form in the space on the upper side of the spin chuck 20 as illustrated by an arrow AR69 by a nozzle base table 68 connected to a base end side of the nozzle arm 67. The nozzle 65 is moved in the arc-like form between the processing position and the standby position on an outer side of the processing cup 40. A relative positional relationship between a center position P66, a peripheral edge position P67, and a standby position P68 located on a movement route of the nozzle 65 is similar to that between the center position P31, the peripheral edge position P32, and the standby position P33.

The nozzle 65 may be lifted up and down. For example, the nozzle 65 is lifted up and down by a nozzle lifting mechanism not shown in the diagrams but is built in the nozzle base table 68. In this case, the nozzle 65 may also be stopped at an upper center position P69 located on an upper side of the center position P66 in the vertical direction. It is also applicable that at least one of the nozzle 30 and the nozzle 60 may be provided to be lifted up and down.

Each of the nozzle 60 and the nozzle 65 is also connected to a processing solution supply source (not shown in the diagrams) via a supply pipe (not shown in the diagrams) in the manner similar to the nozzle 30. A valve is provided to each supply pipe, and supply and stop of the processing solution is switched by opening and closing the valve. Each of the nozzle 60 and the nozzle 65 may have a configuration that plural types of processing solutions including at least pure water are supplied. At least one of the nozzle 30, the nozzle 60, and the nozzle 65 may be a two-fluid nozzle mixing a cleaning solution such as pure water with pressurized air to generate a liquid drop and spraying a mixed fluid of the liquid drop and air to the substrate W. The number of nozzles provided to the processing unit 1 is not limited to three, but it is sufficient that one or more nozzles are provided.

In the example in FIG. 2 and FIG. 3, the fixing nozzle 80 is also provided to the processing unit 1. The fixing nozzle 80 is located on an upper side of the spin chuck 20 and an outer side of an outer peripheral edge of the spin chuck 20 in a radial direction. As a more specific example, the fixing nozzle 80 is provided to a position facing the processing cup 40 described hereinafter in the vertical direction. A discharge port of the fixing nozzle 80 is directed to a side of the substrate W, and an opening axis thereof extends along the horizontal direction, for example. The fixing nozzle 80 also discharges a processing solution to the upper surface of the substrate W held by the spin chuck 20. The processing solution discharged from the fixing nozzle 80 lands a center part of the upper surface of the substrate W, for example.

As exemplified in FIG. 3, the fixing nozzle 80 is connected to a processing solution supply source 83 via a supply pipe 81. A valve 82 is provided to the supply pipe 81. The valve 82 opens and closes a flow path of the supply pipe 81. When the valve 82 is opened, the processing solution supply source 83 supplies the processing solution (for example, pure water) to the fixing nozzle 80 through the supply pipe 81, and the processing solution is discharged from the discharge port of the fixing nozzle 80.

The processing cup 40 surrounding the spin chuck 20 includes an inner cup 41, a middle cup 42, and an outer cup 43 which can be lifted up and down independently from each other. The inner cup 41 has a shape of surrounding the spin chuck 20 and being rotationally symmetric with respect to the rotational axis line CX passing through the center of the substrate W held by the spin chuck 20. This inner cup 41 integrally includes a bottom part 44 having an annular shape in a plan view, a cylindrical inner wall part 45 standing upward from an inner peripheral edge of the bottom part 44, a cylindrical outer wall part 46 standing upward from an outer peripheral edge of the bottom part 44, a guide part 47 standing from between the inner wall part 45 and the outer wall part 46 and extending obliquely upward on a center side (a direction getting close to the rotational axis line CX of the substrate W held by the spin chuck 20) while an upper end part thereof is formed into a smooth arc-like shape, and a cylindrical middle wall part 48 standing upward from between the guide part 47 and the outer wall part 46.

The inner wall part 45 is formed to have a length such that the inner cup 41 in a state of being lifted up to a highest position is housed with an appropriate gap between the cover member 23 and the flanged member 25. The middle wall part 48 is formed to have a length so that the inner cup 41 and the middle cup 42, in a state of getting as close to each other as possible, are housed with an appropriate gap between a guide part 52 described hereinafter of the middle cup 42 and a processing solution separation wall 53.

The guide part 47 includes an upper end part 47b extending obliquely upward on the center side (a direction getting close to the rotational axis line CX of the substrate W) while being formed into a smooth arc-like shape. A disposal groove 49 for collectively disposing of a used processing solution is provided between the inner wall part 45 and the guide part 47. An annular inner pickup groove 50 for collectively picking up the used processing solution is provided between the guide part 47 and the middle wall part 48. Furthermore, an annular outer pickup groove 51 for collectively picking up a processing solution different from that in the inner pickup groove 50 is provided between the middle wall part 48 and the outer wall part 46.

Connected to the disposal groove 49 is an air-solution exhaust mechanism not shown in the diagrams for discharging the processing solution collected in the disposal groove 49 and forcibly performing air exhaustion on an inner part of the disposal groove 49. For example, four air-solution exhaust mechanisms are provided at regular intervals along a circumferential direction of the disposal groove 49. Connected to the inner pickup groove 50 and the outer pickup groove 51 is a pickup mechanism (not shown) for picking up the processing solution collected in each of the inner pickup groove 50 and the outer pickup groove 51 into a pickup tank (not shown) provided on an outer part of the processing unit 1. A bottom part of each of the inner pickup groove 50 and the outer pickup groove 51 is inclined with respect to the horizontal direction at a minute angle, and the pickup mechanism is connected to a lowest position of the bottom part. Accordingly, the processing solution flowing into the inner pickup groove 50 and the outer pickup groove 51 is smoothly picked up.

The middle cup 42 has a shape of surrounding the spin chuck 20 and being rotationally symmetric with respect to the rotational axis line CX passing through the center of the substrate W held by the spin chuck 20. This middle cup 42 integrally includes the guide part 52 and the cylindrical processing solution separation wall 53 connected to this guide part 52.

The guide part 52 includes a cylindrical lower end part 52a coaxial with a lower end part of the guide part 47 on an outer side of the guide part 47 of the inner cup 41, an upper end part 52b extending obliquely upward on the center side (a direction getting close to the rotational axis line CX of the substrate W) while being formed into a smooth arc-like shape from an upper end of the lower end part 52a, and a folding part 52c formed by folding back a tip end part of the upper end part 52b to a lower side. The lower end part 52a is housed in the inner pickup groove 50 with an appropriate gap between the guide part 47 and the middle wall part 48 while the inner cup 41 and the middle cup 42 get as close to each other as possible. The upper end part 52b is provided to be overlapped with the upper end part 47b of the guide part 47 of the inner cup 41 in an up-down direction, and gets close to the upper end part 47b of the guide part 47 with an extremely small interval with respect to the upper end part 47b of the guide part 47 while the inner cup 41 and the middle cup 42 get as close to each other as possible. Furthermore, the folding part 52c formed by folding back the tip end of the upper end part 52b to the lower side has a length so as to be overlapped with a tip end of the upper end part 47b of the guide part 47 in the horizontal direction while the inner cup 41 and the middle cup 42 get as close to each other as possible.

The upper end part 52b of the guide part 52 is formed to have a larger thickness toward the lower side, and the processing solution separation wall 53 has a cylindrical shape so as to extend to the lower side from a lower end outer peripheral edge part of the upper end part 52b. The processing solution separation wall 53 is housed in the outer pickup groove 52 with an appropriate gap between the middle wall part 48 and the outer cup 43 while the inner cup 41 and the middle cup 42 get as close to each other as possible.

The outer cup 43 has a shape of surrounding the spin chuck 20 and being rotationally symmetric with respect to the rotational axis line CX passing through the center of the substrate W held by the spin chuck 20 on the outer side of the guide part 52 of the middle cup 42. This outer cup 43 has a function as a third guide part. The outer cup 43 includes a cylindrical lower end part 43a coaxial with a lower end part 52a of the guide part 52, an upper end part 43b extending obliquely upward on the center side (the direction getting close to the rotational axis line CX of the substrate W) while being formed into a smooth arc-like shape from an upper end of the lower end part 43a, and a folding part 43c formed by folding back a tip end part of the upper end part 43b to a lower side.

The lower end part 43a is housed in the outer pickup groove 51 with an appropriate gap between the processing solution separation wall 53 of the middle cup 42 and the outer wall part 46 of the inner cup 41 while the inner cup 41 and the middle cup 43 get as close to each other as possible. The upper end part 43b is provided to be overlapped with the guide part 52 of the middle cup 42 in the up-down direction, and gets close to upper end part 52b of the guide part 52 with an extremely small interval while the inner cup 41 and the middle cup 42 gets as close to each other as possible. Furthermore, the folding part 43c formed by folding back the tip end part of the upper end part 43b to the lower side is formed so as to be overlapped with the folding part 52c of the guide part 52 in the horizontal direction while the middle cup 42 and the outer cup 43 get as close to each other as possible.

The inner cup 41, the middle cup 42, and the outer cup 43 can be lifted up and down independently from each other. That is to say, a cup lifting mechanism (not shown) is individually provided to each of the inner cup 41, the middle cup 42, and the outer cup 43, thereby independently lifting up and down the cups. Various known mechanisms such as a ball screw mechanism or an air cylinder, for example, can be adopted as such a cup lifting mechanism.

A partition plate 15 is provided to vertically partition an inner space in the chamber 10 around the processing cup 40. The partition plate 15 may be one sheet of plate-like member surrounding the processing cup 40, or may be a plurality of plate-like members connected to each other. A through hole passing in a thickness direction or a notch may be formed in the partition plate 15, and formed in the present embodiment is a through hole through which a support shaft passes to support the nozzle base table 33 of the nozzle 30, the nozzle base table 63 of the nozzle 60, and the nozzle base table 68 of the nozzle 65.

An outer peripheral end of the partition plate 15 is connected to the sidewall 11 of the chamber 10. An end edge part of the partition plate 15 surrounding the processing cup 40 is formed to have a circular shape with a larger diameter than an outer diameter of the outer cup 43. Thus, the partition plate 15 does not become an obstacle to the lifting of the outer cup 43.

An exhaust duct 18 is provided near the floor wall 13 as a part of the sidewall 11 of the chamber 10. The exhaust duct 18 is continuously connected to an exhaust mechanism not shown in the diagrams. Air passing through a space between the processing cup 40 and the partition plate 15 in clean air supplied from the fan filter unit 14 and flowing in the chamber 10 is exhausted outside the device from the exhaust duct 18.

The camera 70 is disposed on an upper side of the partition plate 15 in the chamber 10. The camera 70 includes a charge coupled device as a solid state image sensor and an optical system such as a lens, for example. The camera 70 is provided to take an image of various monitoring targets in the chamber 10 described hereinafter. A specific example of the monitoring target is described in detail hereinafter. The camera 70 is disposed in a position including the various monitoring targets in an imaging field. The camera 70 takes an image of the imaging field for each frame rate to obtain image data, and sequentially outputs the obtained image data to the controller 9.

As illustrated in FIG. 3, an illumination part 71 is provided in a position on an upper side of the partition plate 15 in the chamber 10. When the inner part of the chamber 10 is a darkroom, the controller 9 may control the illumination part 71 so that the illumination part 71 emits light when the camera 70 takes an image.

A configuration of the controller 9 as hardware provided to the substrate processing device 100 is the same as a general computer. Specifically, the controller 9 includes a processing part (processing circuit) such as a CPU performing various types of calculation processing, a transitory recording medium such as a read only memory (ROM) as a read-only memory for recording a basic program therein, a non-transitory recording medium a random access memory (RAM) as a readable/writable memory for recording various pieces of information therein and a magnetic disk recording control software or data and the like therein.

When the CPU in the controller 9 executes a predetermined processing program, the controller 9 controls each operation mechanism of the substrate processing device 100, and the processing in the substrate processing device 100 proceeds. The controller 9 may be achieved by a dedicated hardware circuit which does not need software in achieving a function thereof.

The heating part 29 is a heating means of heating the substrate W. The heating part 29 may not be included. The heating part 29 includes a disk-like hot plate 291 and a heater 292 as a heat generation source. The hot plate 291 is disposed between an upper surface 21a of the spin base 21 and the lower surface of the substrate W held by the chuck pin 26. The heater 292 is embedded in an inner part of the hot plate 291. A heating wire such as a nichrome wire generating heat through electrical conduction is used for the heater 292. When the electrical conduction is applied to the heater 292, the hot plate 291 is heated to have a higher temperature than an environment temperature.

The nozzle 65 discharges not only the processing solution (for example, a rinse solution) but also inactive gas in the processing unit 1. The inactive gas is gas having low reactivity on the substrate W, and includes noble gas such as argon gas or nitrogen, for example. A first inner flow path and a first discharge port for the processing solution and a second inner flow path and a second discharge port for the air are provided to the discharge head of the nozzle 65, for example. The first inner flow path is connected to a processing solution supply source via a first supply pipe, and the second inner flow path is connected to an air supply source via a second supply pipe. A first valve is provided to the first supply pipe, and a second valve is provided to the second supply pipe.

FIG. 5 is a function block diagram schematically illustrating an example of an inner configuration of the controller 9. As exemplified in FIG. 5, the controller 9 includes a monitor processing part 91, a condition setting part 92, and a processing controller 93.

The processing controller 93 controls each configuration in the chamber 10. Specifically, the processing controller 93 controls the spin motor 22, various valves such as the valve 35 or the valve 82, the nozzle base table 33, a motor such as the nozzle base table 63 and the nozzle base table 68, a nozzle lifting mechanism, a cup lifting mechanism, and the fan filter unit 14, for example. When the processing controller 93 controls these configurations in accordance with a predetermined procedure, the processing unit 1 can perform the processing on the substrate W.

The monitor processing part 91 performs monitor processing based on the image data of the image in the chamber taken by the camera 70 and outputted from the camera 70. Accordingly, the monitor processing part 91 can monitor various monitoring targets in the chamber 10.

The condition setting part 92 specifies the monitoring target to be monitored, and changes an imaging condition of the camera 70 in accordance with the monitoring target. Then, the condition setting part 92 notifies the camera 70 of the imaging condition. The imaging condition includes at least one of a definition, a frame rate, and a field range, for example. The camera 70 obtains the image data with the imaging condition transmitted from the condition setting part 92, and outputs the image data to the controller 90.

### <Substrate Processing>

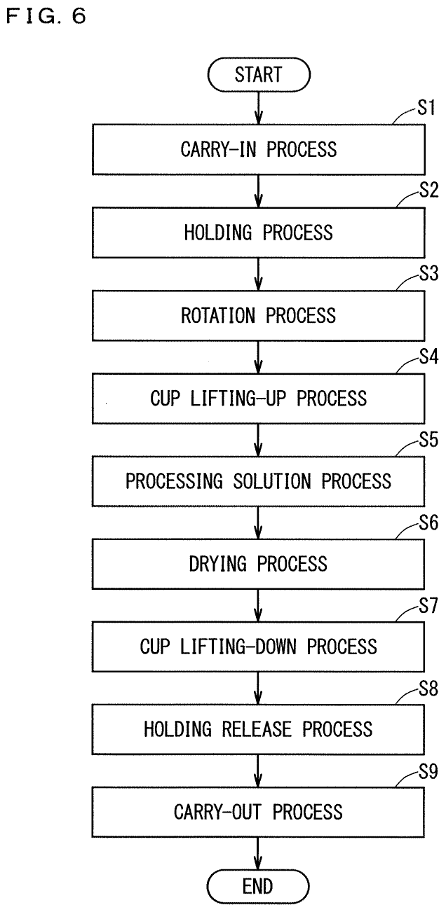

FIG. 6 is a flow chart illustrating an example of a flow of substrate processing. Firstly, the main transfer robot 103 transports the unprocessed substrate W into the processing unit 1 (Step S1: carry-in process). Next, the spin chuck 20 holds the substrate W in the horizontal posture (Step S2: holding process). Specifically, the plurality of chuck pins 26 are moved to respective contact positions, thereby holding the substrate W.

Next, the spin motor 22 starts rotating the substrate W (Step S3: rotation process). Specifically, the spin motor 22 rotates the spin chuck 20, thereby rotating the substrate W held by the spin chuck 20. Next, the cup lifting mechanism lifts up the processing cup 40 (Step S4: cup lifting-up process). Accordingly, the processing cup 40 is stopped at an upper position.

Next, the processing solution is sequentially supplied to the substrate W (Step S5: processing solution process). In this processing solution process (Step S5), the cup lifting mechanism appropriately switches the cup to be lifted up in accordance with a type of the processing solution supplied to the substrate W.

Then, after the processing solution process (Step S5) is finished, the processing unit 1 dries the substrate W (Step S6: drying process). For example, the spin motor 22 increases a rotational speed of the substrate W to dry the substrate W (so-called spin drying).

Next, the cup lifting mechanism lifts down the processing cup 40 (Step S7: cup lifting-down process). Accordingly, the processing cup 40 is located at a lower position.

Next, the spin motor 22 finishes rotating the spin chuck 20 and the substrate W, and the spin chuck 20 releases holding of the substrate W (Step S8: holding release process). Specifically, the plurality of chuck pins 26 are moved to respective release positions, thereby releasing holding of the substrate W.

Next, the main transfer robot 103 transports the substrate W which has been processed from the processing unit 1 (Step S9: carry-out process).

The processing (substrate processing) is performed on the substrate W as described above.

### <Monitor Processing>

The monitor processing part 91 takes an image of the inner part of the chamber 10 using the camera 70, and determines whether or not the above processing on the substrate W processes at an appropriate time (monitor processing). For example, the monitor processing part 91 detects change of a state of the monitoring target (positional change, luminance change, shape change, presence or absence of detection of the monitoring target, for example), and determines that the processing on the substrate W does not appropriately proceed when an amount of change exceeds a predetermined threshold value.

When information regarding the monitoring target is indicated in recipe information described hereinafter, the monitor processing part 91 obtains an image corresponding to the process from the camera 70, and performs the monitor processing. When it is determined that the processing on the substrate W does not appropriately proceed, a result of the determination and an image corresponding thereto are recorded in a recording medium in the controller 9.

The monitoring target monitored by the monitor processing part 91 (that is to say, an imaging target whose image is taken by the camera 70) includes a target object whose image used for the substrate processing can be taken or a phenomenon, appearing in the substrate processing, whose image can be taken. The monitoring target is appropriately switched in accordance with a progress state of the processing as described hereinafter. An example of a monitoring target in the chamber 10 is described hereinafter.

### <Nozzle>

The nozzle 30, the nozzle 60, and the nozzle 65 are appropriately moved in the processing solution process described above. For example, the discharge head 31 of the nozzle 30 is moved from the standby position P33 to the center position P31. At this time, the discharge head 31 is deviated from the center position P31 and is stopped by a motor abnormality in the nozzle base table 33.

Thus, (a position of) the discharge head 31 may be adopted as the monitoring target in the process (period) of moving the nozzle 30. A specific example of the monitor processing monitoring the discharge head 31 as the monitoring target is described hereinafter.

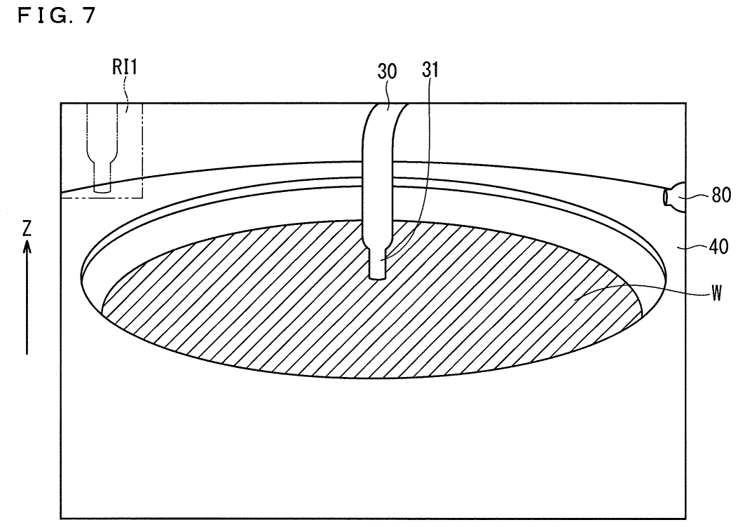

FIG. 7 is a diagram schematically illustrating an example of image data obtained from the camera 70 when the monitor processing is performed. The image data in FIG. 7 includes the discharge head 31 of the nozzle 30 stopped at the center position P31. That is to say, FIG. 7 illustrates image data obtained after the nozzle 30 is moved from the standby position P33 to the center position P31. This image data also includes the processing cup 40 located in the upper position, the substrate W located in an opening of the processing cup 40, and the fixing nozzle 80 in addition to the nozzle 30.

The monitor processing part 91 analyzes the obtained image data and detects the position of the discharge head 31. For example, the monitor processing part 91 may specify the position of the discharge head 31 in the image data by pattern matching using reference image data RI1 including the discharge head 31 previously recorded in a recording medium and the image data. In the example in FIG. 7, the reference image data RI1 is schematically overlapped with the image data by a virtual line. When the position of the nozzle 30 is previously known by the recipe information described hereinafter, it is applicable that a region corresponding to the position of the discharge head 31 is selected from the image data described above to detect presence or absence of the discharge head 31 in the region based on luminance data of the region, for example.

Next, the monitor processing part 91 determines whether or not the detected position of the discharge head 31 is appropriate. For example, the monitor processing part 91 determines whether or not a difference between the position of the discharge head 31 and the preset center position P31 is equal to or smaller than a tolerance value of a predetermined nozzle position. When the difference is equal to or smaller than the tolerance value, the monitor processing part 91 determines that the discharge head 31 is located in the center position P31. In the meanwhile, when the difference is larger than the tolerance value, the monitor processing part 91 determines that the discharge head 31 is not located in the center position P31. That is to say, the monitor processing part 91 determines that abnormality occurs in the nozzle position.

When the abnormality occurs, the monitor processing part 91 may make a notification part (for example, a display or a speaker) not shown in the diagrams transmit notification of the abnormality.

When the abnormality described above occurs, the controller 9 may stop the operation of the processing unit 1 to interrupt the processing on the substrate W. This point is also applied to various types of monitor processing described hereinafter.

In the meanwhile, the nozzle 30 is moved from the standby position P33 to the center position P31 at a predetermined timing. The monitor processing part 91 may specify the position of the nozzle 30 in the image data by the pattern matching using the reference image data RI1 and the image data described above also in a case where it is determined whether or not the position of the nozzle 30 is appropriate in the movement of the nozzle 30.

Although the discharge head 31 of the nozzle 30 is described above as the example of the monitoring target (the imaging target) regarding the substrate processing, the monitoring target regarding the substrate processing is not limited thereto, but may be the substrate W, the chuck pin 26, or the nozzle arm 32 of the nozzle 30, for example.

### <Processing Solution>

The nozzle 30, the nozzle 60, the nozzle 65, and the fixing nozzle 80 appropriately discharge the processing solution process in the processing solution process described above. At this time, when the processing solution is appropriately discharged, the processing can be performed on the substrate W.

Thus, a state of the discharged processing solution may be adopted as the monitoring target in the process of discharging the processing solution from each nozzle. Described is a specific example of the monitoring processing of monitoring the state of the processing solution as the monitoring target.

As the process of monitoring the state of the processing solution as the monitoring target, the substrate W can be heated in the heating part 29 in addition to increase of the rotation speed of the substrate W by the spin motor 22.

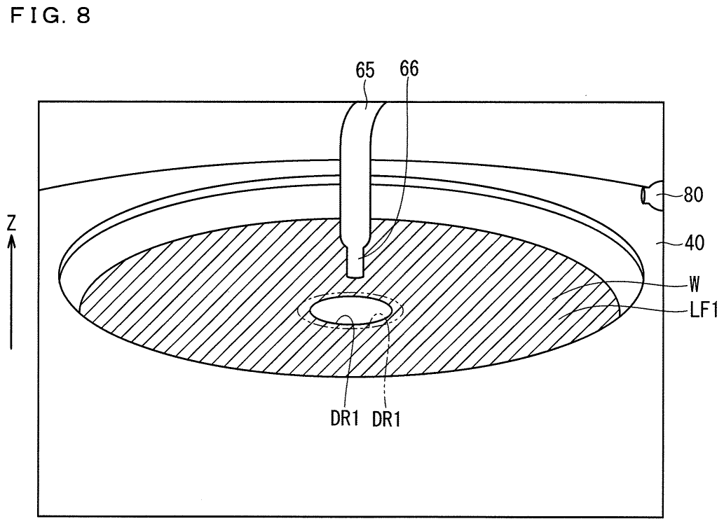

FIG. 8 is a diagram schematically illustrating an example of image data obtained from the camera 70 when the monitor processing is performed. The image data in FIG. 8 includes the discharge head 66 of the nozzle 65 stopped at the center position P66. This image data also includes the processing cup 40 located in the upper position, the substrate W located in the opening of the processing cup 40, a liquid film LF1 formed on the upper surface of the substrate W, and the fixing nozzle 80 in addition to the nozzle 65.

The nozzle 65 is moved from the standby position P68 to the center position P65 to form the liquid film LF1 illustrated in FIG. 8. Next, the nozzle 65 supplies a rinse solution having high volatility than pure water, for example, to the upper surface of the substrate W in rotation. The rinse solution is isopropyl alcohol (IPA), for example. Accordingly, the rinse solution spreads on the whole upper surface of the substrate W, and the processing solution remaining on the upper surface of the substrate W is replaced with the rinse solution after the chemical solution processing, for example.

Next, the nozzle 65 stops discharging the rinse solution while the spin motor 22 stops rotating the substrate W. Accordingly, the rinse solution on the upper surface of the substrate W stands still. That is to say, the liquid film LF1 is formed on the upper surface of the substrate W. Subsequently, electrical conduction is applied to the heater 292 of the heating part 29. Accordingly, a temperature of the heating part 29 is increased, and the substrate W is heated by heat of the heating part 29. Accordingly, a lower layer part of the liquid film LF1 of the rinse solution having contact with the upper surface of the substrate W is also heated. Then, the lower layer part of the liquid film LF1 turns into gas. As a result, a vapor layer of the IPA is formed between the upper surface of the substrate W and the liquid film LF1. That is to say, the liquid film LF1 is in a state of being away from the upper surface of the substrate W.

Next, the nozzle 65 discharges inactive gas. This inactive gas is discharged toward a center part of the liquid film LF1. When the inactive gas is blown onto the liquid film LF1, the liquid film LF1 is moved toward an outer side in a radial direction, and flows to the outer side from the peripheral edge of the substrate W. In accordance with this, a circular opening is formed in the center part of the liquid film LF1 in a plan view (refer to FIG. 8). Since this opening does not include the processing solution such as the rinse solution, the opening is a dry region DR1. Since the liquid film LF1 is pressed by the inactive gas and sequentially moved to the outer side in the radial direction, and flows down from the peripheral edge of the substrate W, the dry region DR1 isotropically spreads as time passes. That is to say, the dry region DR1 extends while maintaining the circular shape in a plan view. In the example in FIG. 8, the dry region FR1 in the image data obtained at a different timing is schematically illustrated by a virtual line.

In the drying process described above, it is difficult to stably form and extend the dry region DR1 as intended. That is to say, when the large number of substrates W are sequentially processed, a position, a shape, or the number of the dry regions DR1 is not in an intended state in the drying process performed on some substrate W in some cases.

For example, the substrate W is heated, and a vapor layer of the rinse solution is formed between the upper surface of the substrate W and the liquid film LF1. At this time, minutes air bubbles occur in the liquid film LF1, and an unintended opening thereby occurs in a part of the liquid film LF1 in some cases. When the opening occurs in a part of the liquid film LF1 before the opening is formed by blowing the inactive gas, vapor of the rinse solution between the upper surface of the substrate W and the liquid film LF1 is leaked from the unintended opening. Then, the vapor layer cannot be maintained, and the drying process cannot be appropriately performed.

Also when the dry region DR1 gradually extends as described above by blowing the inactive gas, the dry region DR1 loses the shape or the plurality of dry regions DR1 occur in some cases. Also in this case, the drying process cannot be appropriately performed.

Thus, the dry region DR1 formed in the liquid film LF1 by blowing the inactive gas from the nozzle 65 is subject to the monitoring target indicating the state of the processing solution.

The monitor processing part 91 analyzes the obtained image data and detects the position and the shape of the dry region DR1. For example, the position and the shape of the dry region DR1 in the image data may be detected by pattern matching using the reference image data obtained by taking an image in a normal state (a state where the circular shape of the dry region DR1 is maintained in the center part) and the image data. When the position where the dry region DR1 is formed is previously known by the recipe information described hereinafter, it is applicable that a region corresponding to the position where the dry region DR1 is formed is selected from the image data described above to detect presence or absence of the dry region DR1 in the region based on luminance data of the region, for example.

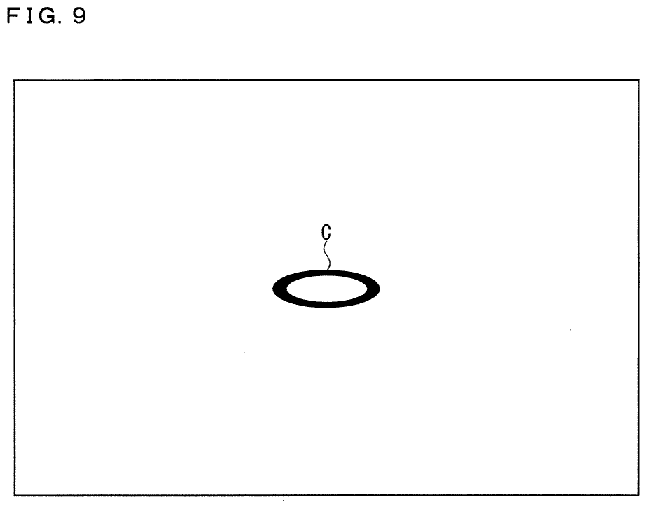

Furthermore, the monitor processing part 91 can calculate a difference between two pieces of image data sequentially obtained after the inactive gas is discharged and obtain a differential image data. FIG. 9 is a diagram schematically illustrating an example of the differential image data. This differential image data includes a closed curve C corresponding to a peripheral edge part of the dry region DR1. When the dry region DR1 extends while the circular shape is maintained, the closed curve C forms an oval shape in the differential image data. In the meanwhile, when the dry region DR1 loses the shape, the closed curve C is distorted and deviated from the oval shape. The monitor processing part 91 can detect the state of the dry region DR1 based on a degree of distortion of the closed curve C.

Although the dry region DR1 formed in the liquid film LF1 is described as the example of the monitoring target (imaging target) regarding the substrate processing in the above description, the monitoring target regarding the substrate processing is not limited thereto, but also applicable is a processing solution in a state of being discharged from the discharge head 66 of the nozzle 65 or a processing solution in a state of being dropped, for example.

### <Image Processing>

When the monitoring target (imaging target) is extracted from the image data as illustrated in FIG. 7 and FIG. 8 to detect a position or a shape the monitoring target, a region of interest (ROI) as a specific region in the image data is set. The plurality of ROIs may be set in one piece of image data, and is preferably set along a shape of the monitoring target.

In the meanwhile, an image in the reference image data is an image of a region corresponding to the ROI, and searched in pattern matching is a position having high similarity between the image in the ROI and the reference image data while the ROI is moved in the whole (or part of) the image data, for example. Then, the monitor processing part 91 determines that the pattern matching has been successfully performed when the similarity described above exceeds a predetermined threshold value. When the position of the monitoring target is previously determined, the ROI is set to the position thereof.

Then, the monitor processing part 91 performs image processing in the ROI, and extracts a coordinate position (for example, an XYZ axis coordinate) of the monitoring target or a shape of the monitoring target. The image processing described above includes application of various kinds of filter processing (for example, smoothing or edge extraction) for each pixel, for example.

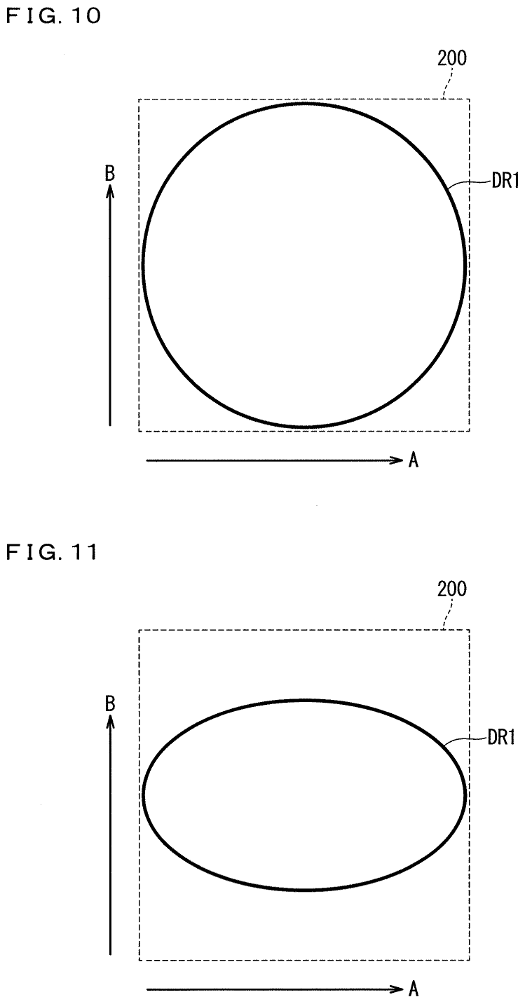

The dry region DR1 as the monitoring target illustrated in FIG. 8 is a circular region in a plan view as exemplified in FIG. 10. Herein, FIG. 10 is a diagram illustrating the drying region DR1 illustrated in FIG. 8 in a plan view.

The ROI in a case illustrated in FIG. 10 is set to a ROI 200, for example. Then, the monitor processing part 91 performs filter processing of applying a filter previously prepared for each pixel in the ROI 200, for example, to detect a state of the monitoring target including a coordinate position or a shape of the monitoring target.

However, since the substrate W and the camera 70 have a positional relationship as illustrated in FIG. 3, a direction of taking an image of the dry region DR1 with the camera 70 is a direction inclined with respect to a plan view. Thus, the dry region DR1 whose image is taken with the camera 70 is an oval region shrinking in a Z axis direction as exemplified in FIG. 8. That is to say, as exemplified in FIG. 11, the dry region DR1 is an oval region shrinking in a B direction. Herein, FIG. 11 is a diagram illustrating the drying region DR1 illustrated in FIG. 10 in a perspective view. FIG. 11 corresponds to a case where the image of the dry region DR1 is taken with the camera 70 with an inclination angle in the B direction with respect to the case in FIG. 10.

The ROI in a case illustrated in FIG. 11 is set to the ROI200, for example, in the manner similar to the case illustrated in FIG. 10. Then, the monitor processing part 91 applies filter processing for each pixel in the ROI 200, for example, thereby extracting a coordinate position or a shape of the monitoring target, for example.

As illustrated in FIG. 11, when the filter processing is applied to the image for each pixel in the ROI 200 in the manner similar to the case in FIG. 10 in the state where the monitoring target (dry region DR1) shrinks in the Z axis direction, the filter processing is not appropriately performed by influence of an image other than the monitoring target included in the ROI 200 (that is to say, an image on both ends of the dry region DR1 in the ROI 200 in the B direction), and as a result, extraction accuracy of the monitoring target is reduced.

Thus, described in the present embodiment is a method of adjusting image processing (filter processing) in accordance with a positional relationship between the monitoring target and the camera 70.

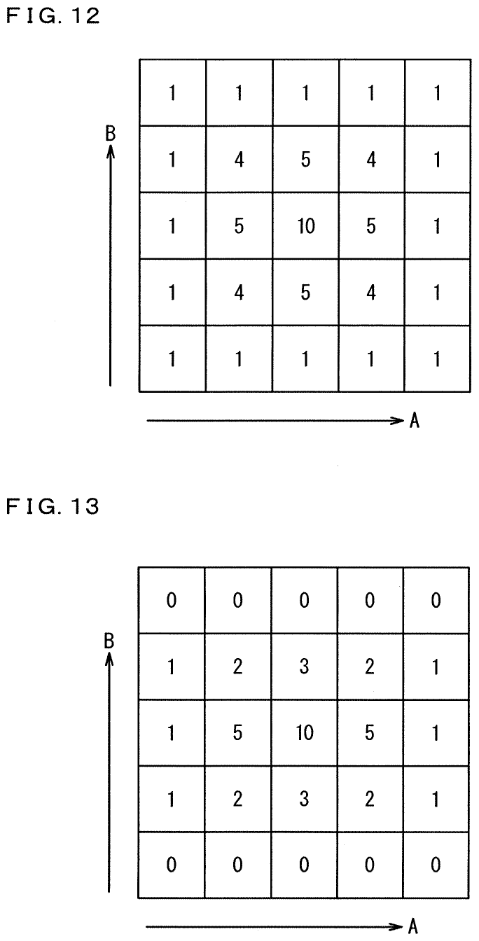

FIG. 12 is a diagram illustrating an example of a filter coefficient of a filter applied to each pixel in the ROI. FIG. 12 illustrates a filter coefficient with a two-dimensional filter matrix (5×5) applied to each pixel in the ROI. The B direction of the filter illustrated in FIG. 12 corresponds to the B direction in FIG. 10 and FIG. 11, and also corresponds to the Z axis direction in FIG. 8.

The filter coefficient illustrated in FIG. 12 is a filter coefficient in a filter applied to the monitoring target in a plan view, and when the plan view is a reference direction in taking the image of the monitoring target with the camera 70, the filter coefficient illustrated in FIG. 12 can be a reference filter coefficient. Since the number of the filter coefficients and a specific numeral value thereof illustrated in FIG. 12 are examples, the number and the numeral value thereof are not limited thereto. The reference direction is not limited to the plan view illustrated in FIG. 12.

In the meanwhile, FIG. 13 is a diagram illustrating the other example of the filter coefficient of the filter applied to each pixel in the ROI. FIG. 13 illustrates a filter coefficient with a two-dimensional filter matrix (5×5) applied to each pixel in the ROI. The B direction of the filter illustrated in FIG. 13 corresponds to the B direction in FIG. 10 and FIG. 11, and also corresponds to the Z axis direction in FIG. 8.

The filter coefficient illustrated in FIG. 13 is a filter coefficient in a filter applied to the monitoring target in a perspective view. That is to say, the imaging direction corresponding to the filter coefficient illustrated in FIG. 13 has an inclination angle with respect to the reference direction described above.

When the filter coefficient illustrated in FIG. 13 is an inclined filter coefficient, the inclined filter coefficient is different from the reference filter coefficient, and all of numeral values in rows on both ends in the B direction (first row and fifth row) are 0. Numeral values of both rows on an inner side, by one line, of the rows on both sides in the B direction (second row and fourth row) of the inclined filter coefficient are equal to or smaller than the reference filter coefficient.

This is caused by correcting the numeral value so that the filter coefficient (that is to say, the first row, the second row, the fourth row, and the fifth row) corresponding to the inclined direction is reduced in accordance with the inclination angle (that is to say, in accordance with a degree of shrinkage of the dry region DR1 in the B direction) with respect to the reference direction. In other words, the inclined filter coefficient is made by correcting the reference filter coefficient based on the positional relationship between the monitoring target and the camera 70.

The dry region DR1 illustrated in FIG. 11 shrinks in the B direction, and has the inclination angle in the B direction with respect to the plan view in FIG. 10. Thus, the inclined filter coefficient illustrated in FIG. 13 is corrected so that the filter coefficient located on the sides of the end part in the B direction as the direction having the inclination angle (that is to say, the first row, the second row, the fourth row, and the fifth row) is reduced. Particularly, the filter coefficient located on the end part in the B direction (that is to say, the first row and the fifth row) is corrected to 0.

When the filter processing is performed using the inclined filter coefficient corrected in such a manner, reduced is influence of the pixel on both ends in the B direction (specifically, the first row, the second row, the fourth row, and the fifth row) on the pixel on which the filter processing is performed. That is to say, a shape of the region to which the filter is applied is substantially deformed to be narrowed in the B direction. Then, suppressed is influence of the image other than the monitoring target included in the ROI 200 (specifically, the image of the dry region DR1 in the ROI 200 on both ends in the B direction), and appropriate filter processing can be achieved. As a result, extraction accuracy of the monitoring target can be kept high.

Herein, an effect of the inclined filter coefficient described above (that is to say, an effect of correcting the filter coefficient) tends to be significant in a case where the number of pixels in the ROI is small (for example, an early stage of formation which the dry region DR1 which has been formed is still small as illustrated in FIG. 8) or a case where a ratio of pixels of a target other than the monitoring target in the ROI is high, for example.

Since the number of the filter coefficients and a specific numeral value thereof illustrated in FIG. 12 and FIG. 13 are examples, the number and the numeral value thereof are not limited thereto. When there are a plurality of cameras taking the image of the monitoring target, the filter coefficient is set to correspond to each camera.

It is applicable that the inclined filter coefficient described above is previously prepared to correspond to a position of the monitoring target previously known from the recipe information, for example, or is calculated by calculating a positional relationship (mainly an inclination angle) between the camera 70 and the monitoring target every time the position of the monitoring target is changed and correcting the reference filter coefficient based on the calculated positional relationship.

As the inclined filter coefficient which is previously prepared, in detecting the chuck pin 26 located on a back side when viewed from the camera 70, correction can be performed in a condition where correction is not performed in an A direction but is performed in the rows on the side of the end parts in the B direction (for example, the first row, the second row, the fourth row, and the fifth row) so that the filter coefficient is reduced to 70% (or a value corrected in such a manner is used), for example. In detecting a height of the processing cup 40, correction can be performed in a condition where correction is not performed in the A direction but is performed in the rows on the side of the end parts in the B direction so that the filter coefficient is reduced to 40% (or a value corrected in such a manner is used), for example.

In detecting a position of the nozzle 30 located in the standby position P33, correction can be performed in a condition where correction is performed in columns on a side of end parts in the A direction (for example, a first column, a second column, a fourth column, and a fifth column) so that the filter coefficient is reduced to 40% (or a value corrected in such a manner is used), but is not performed in the B direction, for example. It is also possible that correction is not performed in the A direction and the B direction in detecting the position of the nozzle 30 located in the center position P31, for example. Herein, the imaging direction of the nozzle 30 viewed from the camera 70 is different between a case where the nozzle 30 is located in the standby position P33 and a case where the nozzle 30 is located in the center position P31. When the imaging direction in the case where the nozzle 30 is located in the center position P31 is a reference direction, the imaging direction in the case where the nozzle 30 is located in the standby position P33 has a constant inclination angle. Thus, even the same monitoring target has a different inclined filter coefficient in a reflection of the inclination angle varied depending on the position thereof.

As described above, when the inclined filter coefficient is previously prepared, calculation for correcting the reference filter coefficient needs not be performed every time the filter processing is performed. Thus, the filter processing can be performed at an appropriate timing without delay.

As a method of correcting the reference filter coefficient based on the positional relationship between the camera 70 and the monitoring target, the reference direction is previously defined for each monitoring target, and prepared is a correction table indicating a degree of correcting a coefficient in the reference filter coefficient to correspond to a magnitude and a direction of the inclination angle with respect to the reference direction. Then, the correction table is recorded in the recording medium of the controller 9, for example.

Next, the positional relationship between the camera 70 and the monitoring target is calculated based on analysis of the image obtained by the camera 70 or output of the other sensor, for example, and furthermore, a corresponding position of the correction table is referenced based on the magnitude and the direction of the inclination angle with respect to the reference direction of the imaging direction of the camera 70. Then, the reference filter coefficient is corrected, and the inclined filter coefficient applied to the filter processing can be obtained.

As described above, when the reference filter coefficient is corrected in each time based on the inclination angle, a state change of the nozzle in an optional position within a range whose image can be taken by the camera 70, for example, can be detected in a case of detecting the position of the swinging nozzle, for example. Thus, the filter processing can be performed while keeping a high degree of freedom.

### <Recipe Information>

Recipe information indicating a procedure of the substrate processing (including each process and various types of conditions in each process) is inputted to the controller 9 from a device on an upper stream side or an operator, for example. When the processing controller 93 controls the processing unit 1 based on the recipe information, the processing unit 1 can perform the processing on the substrate W.

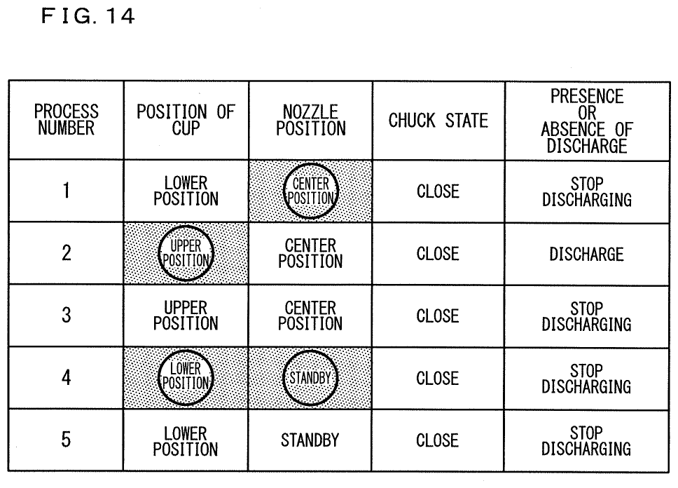

FIG. 14 is a diagram illustrating an example of the recipe information. As exemplified in FIG. 14, the recipe information can include information such as “a process number”, “a position of the cup”, “a position of the nozzle”, “a state of the chuck”, and “presence or absence of discharge”, for example. In addition, information such as “a processing time” or “a discharge flow amount” may be included.

Furthermore, the monitoring target in each process is specified in the recipe information illustrated in FIG. 14. In FIG. 14, each of a position of the nozzle in the center position in a process “1”, a height of the processing cup in the upper position in a process “2”, and a height of the processing cup in the lower position and a position of the nozzle in the standby position in a process “4” is the monitoring target.

In this case, the condition setting part 92 specifies the monitoring target in each process based on the recipe information and sets a condition for taking an image of the monitoring target (including an imaging direction, for example), and transmits notification to the camera 70.

In this manner, the condition setting part 92 specifies one or the plurality of monitoring targets based on the recipe information. The monitoring target needs not necessarily be specified based on the recipe information. Information for specifying the monitoring target may be inputted to the controller 9 from a device on an upper stream side or an operator.

### <Effect Generated by Embodiments Described Above>

Described next is an example of an effect generated by the embodiments described above. In the description hereinafter, the effect is described based on a specific example exemplified in the embodiments described above, however, the specific example may be replaced with the other specific configuration exemplified in the specification of the present application. That is to say, in the description hereinafter, only one of the associated specific configurations is described as a representative in some cases, however, the specific configuration described as the representative may be replaced with the other associated specific configuration.

According to the embodiment described above, in the state detection method, the image of at least one imaging target regarding the processing of the substrate W is taken by the imaging part, and the image is outputted. Herein, the imaging part corresponds to the camera 70, for example. Then, the filter previously prepared is applied to the image in accordance with the imaging target. Then, the state of the imaging target is detected based on the image to which the filter is applied. Herein, the filter coefficient of the filter applied to the image is corrected based on the positional relationship between the imaging target whose image is taken and the camera 70.

According to such a configuration, the filter coefficient is corrected based on the positional relationship between the imaging target and the camera 70; thus, influence of the image other than the imaging target in the filter processing can be suppressed. Thus, the appropriate filter processing is achieved, and reduction of the accuracy of detecting the state of the target can be suppressed. The filter coefficient reflecting the positional relationship between the imaging target and the camera 70 is easily calculated compared with a case of creating the filter coefficient every time the positional relationship therebetween is changed.

Even in a case where the other configurations other than the configurations exemplified in the specification of the present application is appropriately added to the configuration described above, that is to say, the other configurations in the specification of the present application which are not referred to as configurations described above are appropriately added, the similar effects can be produced.

According to the embodiments described above, the direction as a basis in taking the image of the imaging target is the reference direction. The angle between the imaging direction as the direction in which the camera 70 takes the image of the imaging target and the reference direction is the inclination angle. Then, the filter coefficient is corrected based on the inclination angle. According to such a configuration, reduced is influence of the pixel on the both end sides in the inclined direction on the pixel on which the filter processing is performed. Then, suppressed is influence of the image other than the monitoring target included in the ROI 200, and the appropriate filter processing can be achieved.

According to the embodiments described above, the filter is the two-dimensional filter. Then, the filter coefficient located in the end part of the filter in the direction inclined with respect to the reference direction is corrected to 0. According to such a configuration, reduced is influence of the pixel on the both end sides in the inclined direction on the pixel on which the filter processing is performed. That is to say, the shape of the region to which the filter is applied is substantially deformed to be narrowed in the B direction. Then, suppressed is influence of the image other than the monitoring target included in the ROI 200, and the appropriate filter processing can be achieved.

According to the embodiments described above, the plurality of imaging targets includes the first imaging target and the second imaging target located in the position different from the position of the first imaging target. Then, the process of applying the filter to the image is the process of switching the filter between the image of the first imaging target and the image of the second imaging target and applying the filter. According to such a configuration, the inclined filter coefficient reflecting the inclination angle changed in accordance with the position of the monitoring target can be switched and applied to the monitoring target (included is a case of the same monitoring target) located in the different position.

According to the embodiments described above, the state detection device includes the camera 70 for taking the image of at least one imaging target and outputting the image, and the detection part for detecting the state of the imaging target based on the image to which the filter previously prepared in accordance with the imaging target is applied, and the filter coefficient of the filter applied to the image is corrected based on the positional relationship between the imaging target whose image is taken and the camera 70. Herein, the detection part corresponds to the controller 9, for example.

According to such a configuration, the filter coefficient is corrected based on the positional relationship between the imaging target and the camera 70; thus, influence of the image other than the imaging target in the filter processing can be suppressed. Thus, the appropriate filter processing is achieved, and reduction of the accuracy of detecting the state of the target can be suppressed.

Even in a case where the other configurations other than the configurations exemplified in the specification of the present application is appropriately added to the configuration described above, that is to say, the other configurations in the specification of the present application which are not referred to as configurations described above are appropriately added, the similar effects can be produced.

### <Modification Example of Embodiments Described Above>

In the embodiments described above, material properties, materials, dimensions, shapes, relative arrangement relations, conditions for implementation, and so forth for the respective constituent elements may be described, however, these represent a mare example in all aspects, and are not limited to the description in the specification of the present application.

Accordingly, it is understood that numerous modification examples and equivalents which are not exemplified can be devised without departing from the scope of the technique disclosed in the specification of the present application. For example, the technique disclosed in the specification of the present application includes a case of deforming, adding, or omitting at least one constituent element.

Further, in at least one embodiment described above, when names of materials are stated unless otherwise specified, an alloy of the material and other additives, and so forth are included, so far as consistent with the embodiments.

### EXPLANATION OF REFERENCE SIGNS

30 nozzle
60 nozzle
65 nozzle
W substrate

1. A state detection method, comprising:
a step of taking an image of at least one imaging target regarding processing of a substrate by an imaging part and outputting the image;
a step of applying a filter previously prepared to the image in accordance with the imaging target; and
a step of detecting a state of the imaging target based on the image to which the filter is applied, wherein
a filter coefficient of the filter applied to the image is corrected based on a positional relationship between the imaging target whose image is taken and the imaging part.

2. The state detection method according to claim 1, wherein
a direction as a reference in taking the image of the imaging target is a reference direction,
an angle between an imaging direction as a direction in which the imaging part takes the image of the imaging target and the reference direction is an inclination angle, and
the filter coefficient is corrected based on the inclination angle.

3. The state detection method according to claim 2, wherein
the filter is a two-dimensional filter, and
the filter coefficient located at an end portion of the filter in a direction in which the imaging direction is inclined with respect to the reference direction is corrected to 0.

4. The state detection method according to claim 1, wherein
the plurality of imaging targets include a first imaging target and a second imaging target located in a position different from the first imaging target, and
the step of applying the filter to the image is a step of switching the filter between the image of the first imaging target and the image of the second imaging target and applying the filter.

5. A state detection device, comprising:
an imaging part for taking an image of at least one imaging target and outputting the image; and
a detection part for detecting a state of the imaging target based on the image to which a filter previously prepared in accordance with the imaging target is applied, wherein
a filter coefficient of the filter applied to the image is corrected based on a positional relationship between the imaging target whose image is taken and the imaging part.
